(19) United States
(12) Patent Application Publication
(10) Pub. No.: US 2019/0144227 A1
(43) Pub. Date: May 16, 2019

(54) SUBSTRATE CONVEYING DEVICE AND DEPOSITION APPARATUS

(71) Applicant: Industrial Technology Research Institute, Hsinchu (TW)

(72) Inventor: Kuo-Hsin Huang, Hsinchu County (TW)

(73) Assignee: Industrial Technology Research Institute, Hsinchu (TW)

(21) Appl. No.: 15/851,701

(22) Filed: Dec. 21, 2017

(30) Foreign Application Priority Data
Nov. 14, 2017 (TW) 106139271

(51) Int. Cl. B65H 18/14; C23C 16/44; B65H 16/10; B65H 20/02

(52) U.S. Cl. CPC B65H 18/145; B65H 20/02; B65H 16/106; C23C 16/44

(57) ABSTRACT

A substrate conveying device and a deposition apparatus are provided. The substrate conveying device includes a transmission shaft, a plurality of conveying rollers, and a plurality of bearings. The conveying rollers are configured to convey a substrate respectively. Each conveying roller is assembled to the transmission shaft via the corresponding bearing. Each bearing includes a stator and a rotator. Each conveying roller is fixed to the corresponding rotator. The stators are fixed to the transmission shaft. A magnetic repulsion force parallel to an axial direction of the transmission shaft exists between the stator and the rotator. The stator drives the rotator to rotate via a friction force generated by the magnetic repulsion force between the stator and the rotator.

### CROSS-REFERENCE TO RELATED APPLICATION

This application claims the priority benefit of Taiwan application serial no. 106139271, filed on Nov. 14, 2017. The entirety of the above-mentioned patent application is hereby incorporated by reference herein and made a part of this specification.

### BACKGROUND

### Technical Field

The disclosure relates to a conveying device and a deposition apparatus, and more particularly relates to a substrate conveying device and a deposition apparatus.

### Description of Related Art

Now high-efficiency roll-to-roll processing is widely used in the manufacturing processes of many products to reduce the production costs. In order to further raise the yield and lower the production costs, the existing roll-to-roll processing equipment is provided with multiple conveying rollers for conveying various types of substrates at the same time. In such processing, however, there may be a difference in tension between the substrates conveyed by different conveying rollers, which may make it difficult to accurately align some substrates or cause them to go loose. The conveying rollers may be driven individually to solve the aforementioned problem, but it will impose difficulty on design of the mechanism or result in very high equipment costs.

### SUMMARY

The disclosure provides a substrate conveying device and a deposition apparatus, which solve the problem of difference in tension between substrates conveyed by conveying rollers.

A substrate conveying device according to an embodiment of the disclosure includes a transmission shaft, a plurality of conveying rollers, and a plurality of bearings. The conveying rollers are configured to convey a substrate respectively. Each of the conveying rollers is assembled to the transmission shaft via the corresponding bearing. Each of the bearings includes a rotator and a stator. Each of the conveying rollers is fixed to the corresponding rotator. The stator is fixed to the transmission shaft. A magnetic repulsion force parallel to an axial direction of the transmission shaft exists between the rotator and the stator. The stator drives the rotator to rotate by a friction force generated by the magnetic repulsion force between the rotator and the stator.

A deposition apparatus according to an embodiment of the disclosure includes the aforementioned substrate conveying device, an unwinding device, a deposition device, and a winding device. The aforementioned substrate is a deposition mask. The unwinding device is configured to output a target substrate. The deposition device is configured to deposit a film on the target substrate via the deposition mask. The winding device is configured to collect the target substrate, for which deposition has been completed.

Based on the above, in the substrate conveying device and the deposition apparatus according to some embodiments of the disclosure, the stator drives the rotator to rotate by the friction force generated by the magnetic repulsion force between the rotator and the stator. Therefore, the rotator and the stator may rotate relative to each other properly, so as to achieve timely adjustment of tension.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of the deposition apparatus according to an embodiment of the disclosure.

FIG. 2 is a schematic perspective view of the substrate conveying device according to an embodiment of the disclosure.

FIG. 3 is a schematic cross-sectional view along the portion of the bearing of the substrate conveying device of FIG. 2.

FIG. 4 is a schematic exploded view of the bearing of the substrate conveying device of FIG. 2.

FIG. 5A and FIG. 5B are schematic views of the substrate conveying device of FIG. 2 before and after the positions of the bearings are adjusted.

FIG. 6A and FIG. 6B are schematic views of the substrate conveying device before and after the positions of the bearings are adjusted according to another embodiment of the disclosure.

### DESCRIPTION OF THE EMBODIMENTS

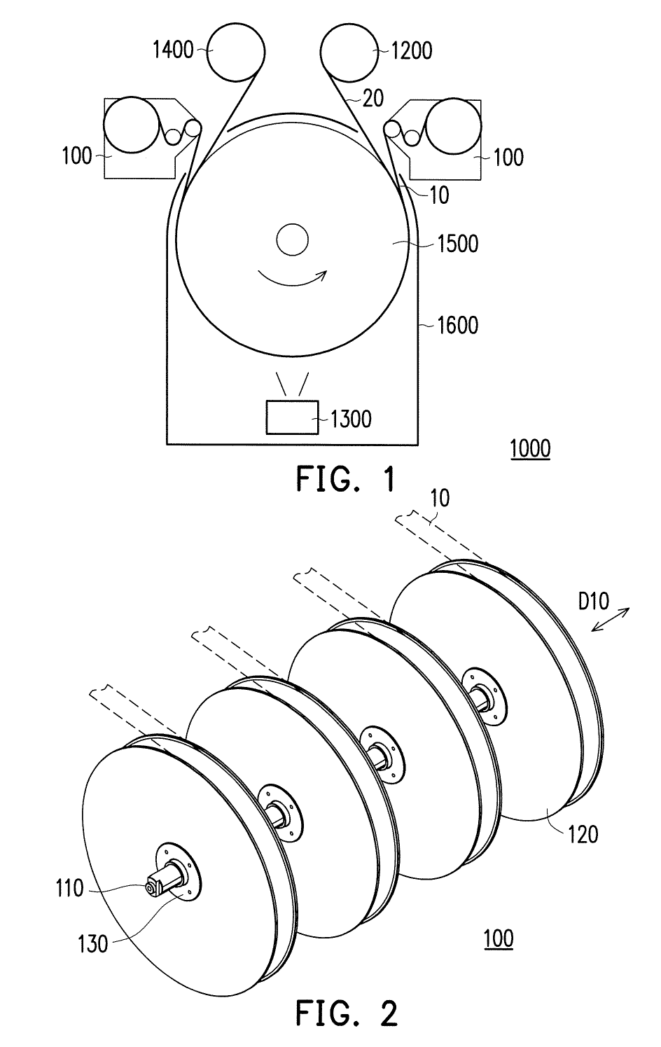

FIG. 1 is a schematic view of a deposition apparatus according to an embodiment of the disclosure. Referring to FIG. 1, the deposition apparatus 1000 according to an embodiment of the disclosure includes at least one substrate conveying device 100, an unwinding device 1400, a deposition device 1300, and a winding device 1200. In this embodiment, two substrate conveying devices 100 are disposed, which are for example the substrate conveying device 100 according to an embodiment of the disclosure as described in detail hereinafter. In other embodiments, the deposition apparatus 1000 may include only one substrate conveying device 100 according to an embodiment of the disclosure as described hereinafter, and another substrate conveying device, which is to be used together with the substrate conveying device 100 for collecting or releasing a substrate 10, may adopt a different design from the substrate conveying device 100. The substrate 10 to be conveyed by the substrate conveying device 100 can be a deposition mask. The substrate 10 to be conveyed by the substrate conveying device 100 of this embodiment is manufactured into a continuous strip and is suitable to be wound into a roll. The unwinding device 1400 is configured to output a target substrate 20. The deposition device 1300 is configured to deposit a film on the target substrate 20 via the deposition mask. The winding device 1200 is configured to collect the target substrate 20 for which deposition has been completed.

In addition, according to the actual needs, the deposition apparatus 1000 of this embodiment may further include a main roller 1500 or other components. Besides, the deposition apparatus 1000 of this embodiment may further include a vacuum chamber 1600. The deposition device 1300 is located in the vacuum chamber 1600. Therefore, the deposition device 1300 of this embodiment is operated in a vacuum environment, but the disclosure is not limited thereto. Moreover, the deposition device 1300 of this embodiment performs deposition on the substrate 20 in the vacuum environment. Thus, the main roller 1500 for carrying the target substrate 20 during the deposition is also located in the vacuum chamber 1600. The substrate conveying device 100, the unwinding device 1400, and the winding device 1200 may be selectively disposed in the vacuum chamber 1600 as well.

FIG. 2 is a schematic perspective view of the substrate conveying device according to an embodiment of the disclosure. Referring to FIG. 2, the substrate conveying device 100 according to an embodiment of the disclosure is applicable to the deposition apparatus 1000 as shown in FIG. 1, but the disclosure is not limited thereto. The substrate conveying device 100 of this embodiment includes a transmission shaft 110, a plurality of conveying rollers 120, and a plurality of bearings 130. Each of the conveying rollers 120 is configured to convey a substrate 10. Each of the conveying rollers 120 is assembled to the transmission shaft 110 via the corresponding bearing 130. Since multiple conveying rollers 120 are driven by one single transmission shaft 110 in this embodiment, the design of the transmission mechanism may be simplified and the space required may be saved. The substrates 10 to be conveyed by the conveying rollers 120 may be the same or different.

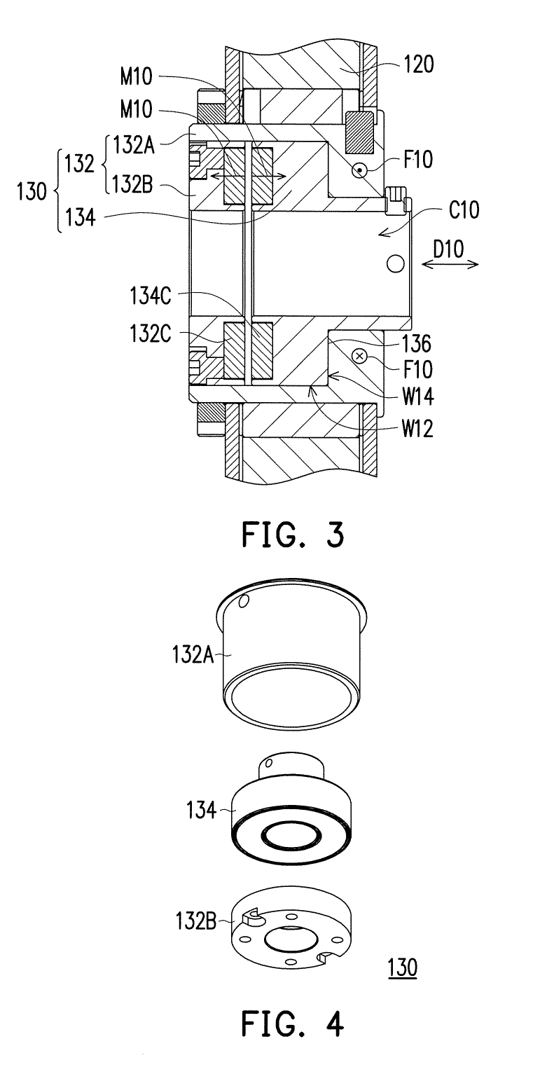

FIG. 3 is a schematic cross-sectional view of the portion of the bearing of the substrate conveying device of FIG. 2, taken along an axial direction of the transmission shaft 110. Referring to FIG. 2 and FIG. 3, each bearing 130 of this embodiment includes a rotator 132 and a stator 134. Each of the conveying rollers 120 is fixed to the corresponding rotator 132. The stator 134 is fixed to the transmission shaft 110. A magnetic repulsion force M10 that is parallel to an axial direction D10 of the transmission shaft 110 exists between the rotator 132 and the stator 134. In other words, the rotator 132 applies the magnetic repulsion force M10 to the stator 134, and the stator 134 applies the magnetic repulsion force M10 to the rotator 132. The stator 134 drives the rotator 132 to rotate by a friction force F10 generated by the magnetic repulsion force M10 between the rotator 132 and the stator 134. In other words, because of the magnetic repulsion force M10, the stator 134 tends to move away from the rotator 132, but the magnetic repulsion force M10 also presses the stator 134 against the other side of the rotator 132, which is away from the side where the magnetic repulsion force M10 is generated. Therefore, when the stator 134 is driven by the transmission shaft 110 to rotate, the friction force F10 is generated on a joint surface where the stator 134 and the rotator 132 are closely pressed against each other, and the friction force F10 drives the rotator 132 to rotate. The friction force F10 is basically perpendicular to the axial direction D10 of the transmission shaft 110.

In the substrate conveying device 100 of this embodiment, one single transmission shaft 110 drives a plurality of conveying rollers 120. Because the remaining roll materials may have different radii or other differences, the substrates 10 on different conveying rollers 120 receive different tensions during the operation. However, since the conveying rollers 120 are not directly fixed to the transmission shaft 110, the conveying rollers 120 are allowed to rotate relative to the transmission shaft 110, so as to achieve adjustment of the tensions received by the substrates 10 as well as prevent reduction of the yield rate resulting from the friction between the substrate 10 and the target substrate 20 of FIG. 1. Moreover, the stator 134 applies the magnetic repulsion force M10 to the rotator 132 in a non-contact manner. Therefore, mechanical wear between the stator 134 and the rotator 132 may be suppressed, which eliminates the need to frequently replace the bearings 130 and maintains the production efficiency.

FIG. 4 is a schematic exploded view of the bearing of the substrate conveying device of FIG. 2. Referring to FIG. 3 and FIG. 4, each rotator 132 of this embodiment includes a cylinder 132A and a chassis 132B, for example. The cylinder 132A has an inner chamber C10. The inner chamber C10 has an axial wall W12 and a radial wall W14. The chassis 132B is assembled to the cylinder 132A. The stator 134 is disposed in the inner chamber C10 and is limited between the chassis 132B and the radial wall W14. When the stator 134 is driven by the transmission shaft 110 to rotate, the magnetic repulsion force that the chassis 132B applies to the stator 134 keeps the stator 134 closely pressed against the radial wall W14 of the inner chamber C10 of the cylinder 132A, and the friction force F10 generated between the stator 134 and the radial wall W14 drives the rotator 132 to rotate. In addition, in this embodiment, at least one of the bearings 130 or each of the bearings 130 may further include a lubricating oil 136, for example, applied to the axial wall W12 and the radial wall W14 for eliminating limits of machining precision and improving relative movement between the rotator 132 and the stator 134, and providing a uniform transmission resistance to each conveying roller 120. The lubricating oil 136 is for example a fluorine-containing oil that has high viscosity, and is suitable for work in a vacuum environment without volatilization.

In addition, the chassis 132B of this embodiment is screwed to the cylinder 132A, for example. Nevertheless, the disclosure is not intended to limit how the chassis 132B and the cylinder 132A are assembled together. Furthermore, each rotator 132 of this embodiment has a first magnet 132C and each stator 134 has a second magnet 134C, and the magnetic repulsion force M10 described above is provided by the first magnet 132C and the second magnet 134C. For example, the first magnet 132C is disposed on a side of the chassis 132B which faces the stator 134, and the second magnet 134C is disposed on a side of the stator 134 which faces the chassis 132B.

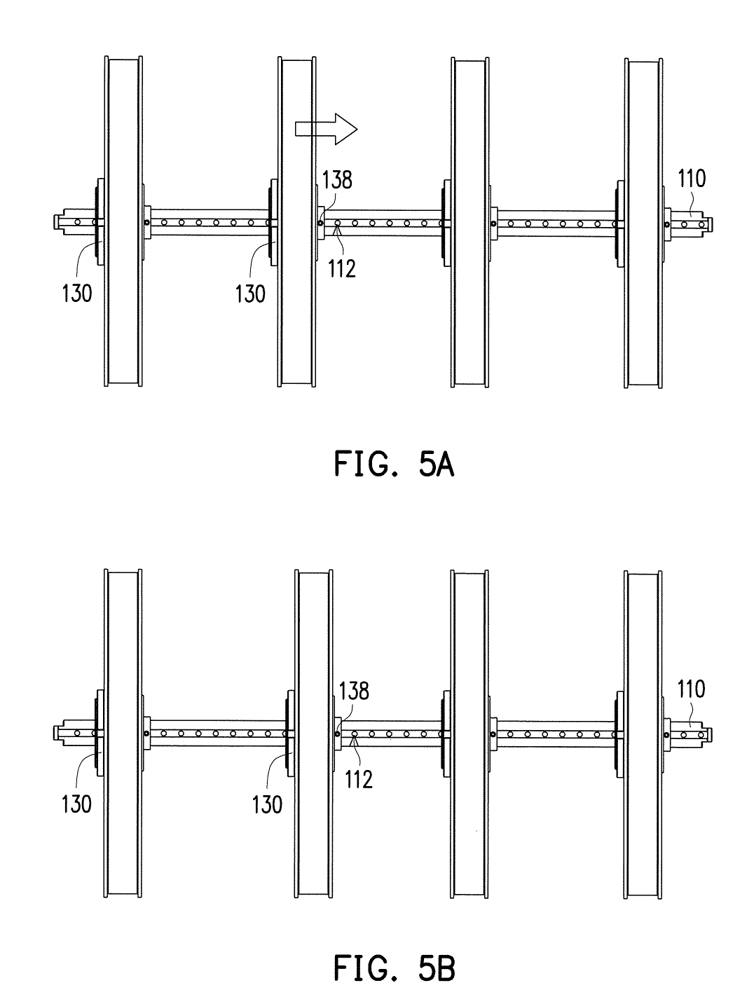

FIG. 5A and FIG. 5B are schematic views of the substrate conveying device of FIG. 2 before and after the positions of the bearings are adjusted. Referring to FIG. 5A and FIG. 5B, the transmission shaft 110 has a plurality of positioning points 112 thereon, for example, and the bearings 130 are detachably assembled to the positioning points 112. For example, each positioning point 112 may be a hole, and the bearing 130 further includes a positioning pin 138, for example. When the bearing 130 is assembled to the desired positioning point 112, the positioning pin 138 is inserted into the corresponding positioning point 112 to achieve positioning, as shown in FIG. 5A. When the bearing 130 needs to be moved to another positioning point 112, the positioning pin 138 is removed from the original positioning point 112 for moving the bearing 130. After the bearing 130 is moved to the new positioning point 112, the positioning pin 138 is inserted into the new positioning point 112 to achieve positioning, as shown in FIG. 5B. In FIG. 5A, the bearings 130 are assembled to the transmission shaft 110 with constant intervals therebetween, while in FIG. 5B, the bearings 130 are assembled to the transmission shaft 110 with variable intervals therebetween, which may be changed as the user needs. Besides, the bearings 130 may be fixed to the transmission shaft 110 and remain immovable. Nevertheless, the disclosure is not limited to the above. In this embodiment, the distances between the positioning points 112 are equal; however, the distances may be different from each other in some other embodiments.

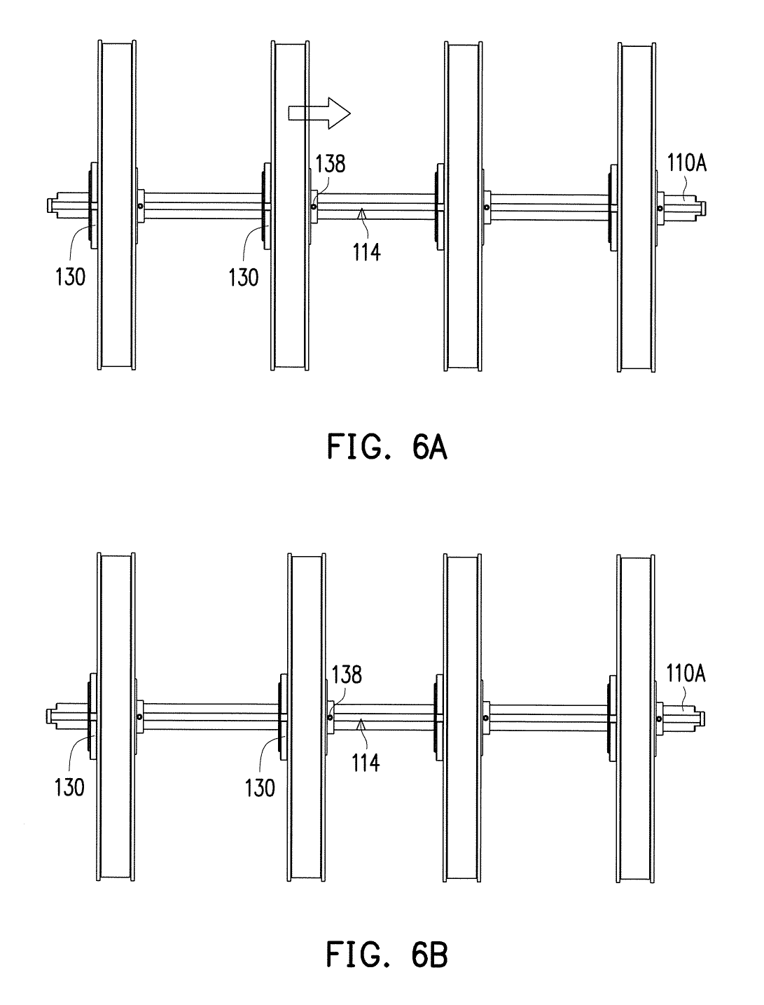

FIG. 6A and FIG. 6B are schematic views of the substrate conveying device before and after the positions of the bearings are adjusted according to another embodiment of the disclosure. Referring to FIG. 6A and FIG. 6B, the substrate conveying device of this embodiment is similar to the substrate conveying device of the embodiment of FIG. 5A, and a difference is that a transmission shaft 110A of this embodiment does not have the positioning points. The transmission shaft 110A of this embodiment has a positioning plane 114 instead. The bearings 130 are also positioned by the positioning pins 138. When the bearing 130 reaches the desired position, the positioning pin 138 is disposed through the bearing 130 to abut tightly on the positioning plane 114. Since the positioning pin 138 and the positioning plane 114 are tightly in contact with each other, the friction force may prevent the positioning pin 138 and the positioning plane 114 from being displaced relative to each other, so as to position the bearing 130 at the fixed position on the transmission shaft 110A, as shown in FIG. 6A. When the bearing 130 needs to be moved to another position, the positioning pin 138 and the positioning plane 114 are released from the contact state for moving the bearing 130. After the bearing 130 is moved to the new position, the positioning pin 138 is disposed again to tightly abut the new position on the positioning plane 114 to achieve positioning, as shown in FIG. 6B. The configuration of FIG. 6A and FIG. 6B makes it possible to position the bearing 130 at any position on the transmission shaft 110A, without being limited to the positions of the positioning points 112 as shown in FIG. 5A.

To sum up, in the substrate conveying device and the deposition apparatus of the disclosure, the conveying rollers are not directly fixed to the transmission shaft, and are driven to rotate by the friction force generated by the stator due to the magnetic repulsion force. Therefore, when the tension received by the substrates on the conveying rollers is too large or too small, the rotator and the stator may rotate relative to each other properly to achieve timely adjustment of the tension.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A substrate conveying device, comprising:
a transmission shaft;
a plurality of conveying rollers configured to convey a substrate respectively;
a plurality of bearings, wherein each of the conveying rollers is assembled to the transmission shaft via the corresponding bearing, and each of the bearings comprises:
a rotator, wherein each of the conveying rollers is fixed to the corresponding rotator; and
a stator fixed to the transmission shaft, wherein a magnetic repulsion force parallel to an axial direction of the transmission shaft exists between the rotator and the stator, and the stator drives the rotator to rotate by a friction force generated by the magnetic repulsion force between the rotator and the stator.

2. The substrate conveying device according to claim 1, wherein each of the rotators comprises:
a cylinder having an inner chamber, wherein the inner chamber has an axial wall and a radial wall; and
a chassis assembled to the cylinder, wherein the corresponding stator is disposed in the inner chamber and limited between the chassis and the radial wall, and when the transmission shaft rotates, the magnetic repulsion force between the chassis and the corresponding stator generates the friction force between the corresponding stator and the radial wall.

3. The substrate conveying device according to claim 2, wherein at least one of the bearings further comprises a lubricating oil applied to the axial wall and the radial wall.

4. The substrate conveying device according to claim 2, wherein each of the bearings further comprises a lubricating oil applied to the axial wall and the radial wall.

5. The substrate conveying device according to claim 2, wherein the chassis are screwed to the cylinders.

6. The substrate conveying device according to claim 1, wherein each of the rotators comprises a first magnet and each of the stators comprises a second magnet, and the magnetic repulsion force exists between the first magnet and the second magnet.

7. The substrate conveying device according to claim 1, wherein the bearings are assembled to the transmission shaft with constant intervals therebetween.

8. The substrate conveying device according to claim 1, wherein the bearings are assembled to the transmission shaft with different intervals therebetween.

9. The substrate conveying device according to claim 1, wherein the transmission shaft has a plurality of positioning points, and the bearings are detachably assembled to the positioning points.

10. The substrate conveying device according to claim 1, wherein the transmission shaft has a positioning plane, each of the bearings further comprises a positioning pin, and the bearings are detachably positioned on the transmission shaft by contacts between the positioning pins and the positioning plane.

11. A deposition apparatus, comprising:
the substrate conveying device according to claim 1, wherein the substrate is a deposition mask;
an unwinding device configured to output a target substrate;
a deposition device configured to deposit a film on the target substrate via the deposition mask; and
a winding device configured to collect the target substrate for which deposition has been completed.

12. The deposition apparatus according to claim 11, wherein each of the rotators comprises:
a cylinder having an inner chamber, wherein the inner chamber has an axial wall and a radial wall; and
a chassis assembled to the cylinder, wherein the corresponding stator is disposed in the inner chamber and limited between the chassis and the radial wall, and when the transmission shaft rotates, the magnetic repulsion force between the chassis and the corresponding stator generates the friction force between the corresponding stator and the radial wall.

13. The deposition apparatus according to claim 12, wherein at least one of the bearings further comprises a lubricating oil applied to the axial wall and the radial wall.

14. The deposition apparatus according to claim 12, wherein each of the bearings further comprises a lubricating oil applied to the axial wall and the radial wall.

15. The deposition apparatus according to claim 12, wherein the chassis are screwed to the cylinders.

16. The deposition apparatus according to claim 11, wherein each of the rotators comprises a first magnet and each of the stators comprises a second magnet, and the magnetic repulsion force exists between the first magnet and the second magnet.

17. The deposition apparatus according to claim 11, wherein the bearings are assembled to the transmission shaft with constant intervals therebetween.

18. The deposition apparatus according to claim 11, wherein the transmission shaft has a plurality of positioning points, and the bearings are detachably assembled to the positioning points.

19. The deposition apparatus according to claim 11, wherein the transmission shaft has a positioning plane, each of the bearings further comprises a positioning pin, and the bearings are detachably positioned on the transmission shaft by contacts between the positioning pins and the positioning plane.

20. The deposition apparatus according to claim 11, further comprising a vacuum chamber, wherein the deposition device is located in the vacuum chamber.
